(19) United States
(12) Patent Application Publication
(10) Pub. No.: US 2023/0101574 A1
(43) Pub. Date: Mar. 30, 2023

(54) Method for producing carbon-coated silicon particles

(71) Applicant: Wacker Chemie AG, Munich (DE)

(72) Inventors: Jennifer WEGENER, München (DE); Christoph Dräger, München (DE)

(73) Assignee: Wacker Chemie AG, Munich (DE)

(21) Appl. No.: 17/911,207

(22) PCT Filed: Mar. 18, 2020
(86) PCT No.: PCT/EP2020/057362

§ 371 Date: Sep. 13, 2022

(51) Int. Cl. C23C 16/448; C23C 16/26; C23C 16/44; H01M 4/04; H01M 4/36; H01M 4/38; H01M 4/134; H01M 4/587

(52) U.S. Cl. CPC C23C 16/448; C23C 16/26; C23C 16/4417; H01M 4/0428; H01M 4/366; H01M 4/386; H01M 4/134; H01M 4/587; H01M 2004/027

(57) ABSTRACT

A method or process for producing non-aggregated carbon-coated silicon particles and lithium-ion batteries utilizing the same. The process includes providing or producing a dry mixture by mixing silicon particles and polyacrylonitrile present in solid form. Thermally decomposing the polyacrylonitrile present in solid form in the dry mixture to form gaseous carbon precursors. Forming gaseous carbon precursors that are carbonized in the presence of the silicon particles by CVD processes (chemical vapor deposition, chemical gas phase deposition). Where the non-aggregated carbon-coated silicon particles have an average particle diameters d₅₀ of from 1 to 15 μm and containing ≤10% by weight of carbon and ≥90% by weight of silicon, each based on the total weight of the carbon-coated silicon particles.

The invention relates to processes for producing carbon-coated silicon particles and also to processes for producing lithium-ion batteries.

Among the commercially available electrochemical energy storage means, rechargeable lithium-ion batteries currently have the highest specific energy, of up to 250 Wh/kg. The negative electrode material (“anode”) used in practice is currently mainly graphitic carbon. However, graphite has a relatively low electrochemical capacity of a theoretical 372 mAh/g, which corresponds to only about a tenth of the electrochemical capacity theoretically achievable with lithium metal. In contrast, silicon has the highest known storage capacity for lithium ions, at 4199 mAh/g. Disadvantageously, silicon-containing electrode active materials undergo extreme volume changes of up to approximately 300% when charging or discharging with lithium. This change in volume results in strong mechanical stressing of the active material and the overall electrode structure which via electrochemical grinding leads to a loss in electrical contacting and hence to destruction of the electrode with a loss of capacity. Furthermore, the surface of the silicon anode material used reacts with constituents of the electrolyte to continuously form passivating protective layers (solid electrolyte interphase; SEI), which leads to an irreversible loss of mobile lithium.

In order to counteract such problems, a number of works have recommended carbon-coated silicon particles as an active material for anodes of lithium-ion batteries. For instance, Liu, Journal of The Electrochemical Society, 2005, 152 (9), pages A17198 to A1725, describes carbon-coated silicon particles having a high carbon proportion of 27% by weight. Silicon particles coated with 20% by weight of carbon are described by Ogumi in the Journal of The Electrochemical Society, 2002, 149 (12), pages A1598 to A1603. JP2002151066 reports a carbon proportion of 11% to 70% by weight for carbon-coated silicon particles. The coated particles of Yoshio, Chemistry Letters, 2001, pages 1186 to 1187, contain 20% by weight of carbon and have an average particle size of 18 μm. The layer thickness of the carbon coating is 1.25 μm. The publication by N.-L. Wu, Electrochemical and Solid-State Letters, 8 (2), 2005, pages A100 to A103, discloses carbon-coated silicon particles having a carbon proportion of 27% by weight.

JP2004-259475 teaches processes of coating silicon particles with non-graphite carbon material and optionally graphite followed by carbonizing, the process cycle of coating on carbonizing being repeated multiple times. In addition, JP2004-259475 reports using the non-graphite carbon material and any graphite in the form of a suspension for the surface coating. Such process measures are known to lead to aggregated carbon-coated silicon particles. U.S. Pat. No. 8,394,532 also produced carbon-coated silicon particles from a dispersion. 20% by weight of carbon fibers are specified for the starting material, based on silicon.

EP1024544 is concerned with silicon particles having surfaces which are completely covered with a carbon layer. However, only aggregated carbon-coated silicon particles are specifically disclosed, as illustrated by the examples with reference to the average particle diameters of silicon and the products. As carbon precursors, EP1024544 mentions polymers, such as phenol resins, imide resins, resins of aromatic sulfonic salts, pitch or tar, or alternative low molecular weight hydrocarbons such as benzene, toluene, naphthalene, phenol, methane, ethane or hexane. EP2919298 teaches processes for producing Si/C composites starting from mixtures containing silicon particles and predominantly polymers, such as polyvinyl chloride, in which the polymer is first melted and then pyrolyzed and the pyrolysis products are lastly ground, which implies aggregated particles. US2016/0104882 relates to composite materials in which a multiplicity of silicon particles are embedded in a carbon matrix. The individual carbon-coated silicon particles are therefore in the form of aggregates.

US2009/0208844 describes silicon particles having a carbon coating containing electrically conductive elastic carbon material, specifically expanded graphite. This document discloses silicon particles on the surface of which expanded graphite particles are attached in particulate form via a carbon coating. Process-related points of reference for producing non-aggregated carbon-coated silicon particles cannot be found in US2009/0208844. US2012/0100438 contains porous silicon particles having a carbon coating; however, it does not make any specific statements regarding the production of the coating and the proportions of carbon and silicon in the particles. WO2018/082880, for the production of carbon-coated silicon particles, on the one hand describes a CVD process (chemical vapor deposition) in which hydrocarbons having 1 to 10 carbon atoms are used as carbon precursors and the silicon particles are kept in motion during the CVD process. Alternatively, in WO2018/082880, dry mixtures of silicon particles and polymeric carbon precursors are heated until the polymeric carbon precursors have completely melted, and only then are the molten polymeric carbon precursors carbonized. For the production of anodes, EP1054462 teaches coating current collectors with silicon particles and binders and then carbonizing them.

Against this background, one object was to provide processes for modifying silicon particles, by means of which active material for anodes of lithium-ion batteries is made accessible, said processes enabling lithium-ion batteries having high initial reversible capacities and additionally having stable electrochemical behavior with minimal decline in reversible capacity (fading) in subsequent cycles.

The invention provides processes for producing non-aggregated carbon-coated silicon particles

having average particle diameters d₅₀ of from 1 to 15 μm and containing ≤10% by weight of carbon and ≥90% by weight of silicon, each based on the total weight of the carbon-coated silicon particles,

by producing a dry mixture by mixing silicon particles and polyacrylonitrile present in solid form,

characterized in that the polyacrylonitrile present in solid form in the dry mixture is thermally decomposed to form gaseous carbon precursors and

the gaseous carbon precursors thus formed are carbonized in the presence of the silicon particles by CVD processes (chemical vapor deposition, chemical gas phase deposition).

The non-aggregated carbon-coated silicon particles produced in accordance with the invention are also referred to hereinafter as carbon-coated silicon particles for short.

Surprisingly, the process according to the invention affords carbon-coated silicon particles which are not aggregated. Surprisingly, there was only negligible occurrence, if any, of sticking or sintering, and hence aggregation, of different particles. This was all the more surprising since sticky carbon species can be present at the elevated temperatures during the carbonization, and these can lead to caking of the particles. Surprisingly, non-aggregated carbon-coated silicon particles were nevertheless obtained according to the invention.

The silicon particles used in the process according to the invention have volume-weighted particle size distributions with diameter percentiles d₅₀ of preferably 1 to less than 15 μm, particularly preferably 2 to less than 10 μm and most preferably 3 to less than 8 μm (determination: with a Horiba LA 950 measuring instrument as described hereinbelow for the carbon-coated silicon particles).

The silicon particles are preferably not aggregated and particularly preferably are not agglomerated. Aggregated means that spherical or very largely spherical primary particles, such as for example are initially formed in gas-phase processes during the production of the silicon particles, coalesce to form aggregates in the course of the reaction of the gas-phase process. Aggregates or primary particles can also form agglomerates. Agglomerates are a loose conglomeration of aggregates or primary particles. Agglomerates may easily be split back up into the aggregates using typically employed kneading or dispersing methods. Aggregates cannot or can only partly be broken down into the primary particles with these methods. As a result of their formation, aggregates and agglomerates inevitably have entirely different particle shapes than the preferred silicon particles. For determining aggregation, the statements made concerning the carbon-coated silicon particles applies analogously for the silicon particles.

The silicon particles preferably have splintery particle shapes.

The silicon particles are preferably based on elemental silicon. Elemental silicon is to be understood as meaning preferably high-purity and/or polycrystalline and/or a mixture of polycrystalline and amorphous silicon, optionally comprising a small proportion of foreign atoms (for example B, P, As).

The silicon particles preferably contain ≥95% by weight, more preferably ≥98% by weight, particularly preferably ≥99% by weight and most preferably ≥99.5% by weight of silicon. The % by weight figures are based on the total weight of the silicon particles, in particular on the total weight of the silicon particles minus their oxygen content. The inventive proportion of silicon in the silicon particles can be determined by ICP (inductively coupled plasma) optical emission spectrometry according to EN ISO 11885:2009 using an Optima 7300 DV measuring instrument from Perkin Elmer.

The silicon particles generally contain silicon oxide. Silicon oxide is preferably located at the surface of the silicon particles. Silicon oxide may be formed for example in the production of the silicon particles by grinding or during storage in air. Such oxide layers are also referred to as native oxide layers.

The silicon particles generally have on their surface an oxide layer, in particular a silicon oxide layer, having a thickness of preferably 0.5 to 30 nm, particularly preferably 1 to 10 nm and most preferably 1 to 5 nm (determination method: for example HR-TEM (high-resolution transmission electron microscopy)).

The silicon particles preferably contain 0.1% to 5.0% by weight, more preferably 0.1% to 2% by weight, particularly preferably 0.1% to 1.5% by weight and most preferably 0.2% to 0.8% by weight of oxygen based on the total weight of the silicon particles (determined using a Leco TCH-600 analyzer).

The surface of the silicon particles may possibly be covered by an oxide layer or by other inorganic and organic groups. Particularly preferred silicon particles bear, on the surface, Si—OH or Si—H groups or covalently bonded organic groups such as for example alcohols or alkenes.

Preference is given to polycrystalline silicon particles. Polycrystalline silicon particles have crystallite sizes of preferably ≤200 nm, more preferably ≤100 nm, more preferably still ≤60 nm, particularly preferably ≤20 nm, most preferably ≤18 nm and most preferably of all ≤16 nm. The crystallite size is preferably ≥3 nm, particularly preferably ≥6 nm and most preferably ≥9 nm. The crystallite size is determined by X-ray diffraction pattern analysis according to the Scherrer method from the full width at half maximum of the diffraction reflection belonging to Si(111) at 2⊖=28.4°. The standard for the X-ray diffraction pattern of silicon is preferably the NIST X-ray diffraction standard reference material SRM640C (monocrystalline silicon).

The silicon particles may for example be produced by grinding processes, for example wet grinding or preferably dry grinding processes. Preference is given here to using jet mills, for example opposed jet mills, or impact mills, planetary ball mills or stirred ball mills. Wet grinding is generally effected in a suspension with organic or inorganic dispersion media. This may involve the use of established methods, as for example described in the patent application with the application number DE 102015215415.7.

Polyacrylonitrile is generally based on at least 10 acrylonitrile monomer units. Polyacrylonitrile may for example be present in the form of a powder or granular material. The melting point of polyacrylonitrile is known to be 300° C. At temperatures lower than 300° C., polyacrylonitrile is generally in solid form. According to the invention, the polyacrylonitrile present in solid form is thermally decomposed without an intermediate melting stage, for example by appropriate thermal treatment or by dispensing with a holding stage in the melting range of polyacrylonitrile.

Besides polyacrylonitrile, one or more further polymers, other than polyacrylonitrile, or other hydrocarbon compounds may optionally be used as carbon precursors in the process according to the invention. Preference is given to using ≥70% by weight and particularly preferably ≥90% by weight of polyacrylonitrile, based on the total weight of carbon precursors used overall. Most preferably, no further carbon precursors are used besides polyacrylonitrile.

Dry mixtures containing polyacrylonitrile and silicon particles are used in the process according to the invention. The silicon particles and the polyacrylonitrile are generally present alongside one another, in particular as separate particles or granules, in the dry mixtures. The dry mixtures preferably do not contain any agglomerates containing silicon particles and polyacrylonitrile, and in particular do not contain any aggregates containing silicon particles and polyacrylonitrile. The dry mixtures are preferably in powder form.

The dry mixtures contain preferably 20% to 99% by weight, more preferably 50% to 98% by weight, more preferably still 60% to 95% by weight, particularly preferably 70% to 90% by weight and most preferably 75% to 85% by weight, of silicon particles, based on the total weight of the dry mixtures.

The dry mixtures contain preferably 1% to 80% by weight, more preferably 2% to 50% by weight, more preferably still 5% to 40% by weight, particularly preferably 10% to 30% by weight and most preferably 15% to 25% by weight, of polyacrylonitrile, based on the total weight of the dry mixtures. The total amount of polyacrylonitrile is generally selected so that there is the desired extent of carbon deposition.

Moreover, the dry mixtures may contain one or more further components, such as conductive additives, for example graphite, conductive carbon black, graphene, graphene oxide, graphene nanoplatelets, carbon nanotubes, carbon fibers or metallic particles such as copper. Preferably, no conductive additives are present.

The dry mixtures generally do not contain any solvent. The process according to the invention is generally conducted in the absence of solvent. However, this does not preclude the starting materials used from containing any residual contents of solvent, for example as a result of their production.

Preferably, the dry mixtures, in particular the silicon particles and/or polyacrylonitrile, contain ≤2% by weight, particularly preferably ≤1% by weight and most preferably ≤0.5% by weight, of solvent.

Examples of solvents include inorganic solvents such as water, or organic solvents, in particular hydrocarbons, ethers, esters, nitrogen-functional solvents, sulfur-functional solvents, alcohols such as ethanol and propanol, benzene, toluene, dimethylformamide, N,N-dimethylacetamide, N-methyl-2-pyrrolidone, N-ethyl-2-pyrrolidone and dimethyl sulfoxide.

The silicon particles and polyacrylonitrile can be mixed to produce the dry mixtures in a conventional manner, for example by mechanical mixing, for example at temperatures of 0 to 50° C., preferably 15 to 35° C. It is possible to use standard mixers, for example pneumatic mixers, freefall mixers, such as container mixers, cone mixers, drum roller mixers, gyro mixers, tumble mixers or displacement and impeller mixers such as drum mixers and screw mixers. Mixing can also be accomplished using mills commonly used for the purpose, such as planetary ball mills, stirred ball mills or drum mills. In general, no solvents, and especially not the above-mentioned solvents, are used in the production of the dry mixtures starting from silicon particles and polyacrylonitrile present in solid form. The dry mixtures are thus generally not produced by spray drying.

The thermal decomposition of polyacrylonitrile is conducted at temperatures of preferably ≥350° C., particularly preferably ≥360° C. and most preferably ≥370° C. The thermal decomposition of polyacrylonitrile is conducted at temperatures of preferably ≤500° C., particularly preferably ≤450° C. and most preferably ≤400° C. Alternatively, the thermal decomposition may also be effected within a temperature range starting at the aforementioned temperatures up to the upper limit of the carbonization temperature mentioned further below. The decomposition temperature can be determined by means of thermogravimetric analysis (TGA).

In the thermal decomposition of polyacrylonitrile various decomposition products, for example acrylonitrile, acetonitrile, vinylacetonitrile, HCN and/or NH₃, may be formed. Such decomposition products are generally present in gas form under the conditions employed for the polyacrylonitrile decomposition.

The dry mixtures are preferably heated rapidly until the thermal decomposition of polyacrylonitrile begins. The temperature of the dry mixtures is preferably continuously raised until thermal decomposition occurs. Prior to the start of the thermal decomposition, the heated dry mixtures are preferably not held at a temperature, especially not at a temperature in the range from the melting point to the temperature at which the thermal decomposition of polyacrylonitrile begins.

The dry mixtures can be heated by discontinuously or, preferably, continuously increasing the temperature. For example, the dry mixtures can be introduced into a preheated furnace for discontinuous heating. Continuous heating may involve heating at a constant or variable heating rate, but generally with a positive heating rate. The heating rate is in the range from preferably 1 to 1000° C. per minute, particularly preferably 1 to 100° C. per minute and most preferably 1 to 10° C. per minute. In an alternative embodiment, the heating rate is in the range from preferably 1 to 20° C. per minute, particularly preferably 1 to 15° C. per minute and most preferably 1 to 10° C. per minute. In a further alternative embodiment, the heating rate is in the range from preferably 10 to 1000° C. per minute, particularly preferably 20 to 500° C. per minute and most preferably 50 to 100° C. per minute.

During the performance of the process according to the invention, polyacrylonitrile is generally not in a liquid or molten form, preferably not even partially. In general, melting of polyacrylonitrile essentially does not take place or does not take place to a significant extent prior to or during the thermal decomposition of polyacrylonitrile. The proportion of polyacrylonitrile that is melted during the performance of the process according to the invention is preferably ≤20% by weight, more preferably ≤10% by weight and particularly preferably ≤5% by weight, based on the total weight of the polyacrylonitrile used overall. Preferably, polyacrylonitrile present in solid form is decomposed by heating to a temperature of ≥350° C., wherein ≤10% by weight, in particular ≤5% by weight, of the polyacrylonitrile is melted, based on the total weight of the polyacrylonitrile used. Particularly preferably, polyacrylonitrile present in solid form is decomposed by heating to a temperature of ≥350° C., without polyacrylonitrile being present in the form of a melt prior to or during the decomposition. Most preferably, polyacrylonitrile is not melted prior to or during the decomposition. Most preferably as well, no polyacrylonitrile at all is melted during the performance of the process according to the invention. This decomposition behavior can be ascertained by means of thermogravimetric analysis (TGA).

The polyacrylonitrile has decomposed to an extent of preferably ≥10% by weight, more preferably ≥30% by weight, more preferably still ≥40% by weight, particularly preferably ≥50% by weight and most preferably ≥60% by weight at the time at which carbonization starts, based on the polyacrylonitrile used (determination by means of thermogravimetric analysis (TGA)).

In the carbonization by CVD processes according to the invention, the gaseous carbon precursors formed from polyacrylonitrile are decomposed and silicon particles are coated with carbon, resulting in carbon-coated silicon particles being obtained. As is customary, the gaseous carbon precursors decompose on the hot surface of the silicon particles, with deposition of carbon.

The thermal decomposition of polyacrylonitrile and the carbonization of the gaseous carbon precursors formed from polyacrylonitrile may be effected successively in terms of time or preferably at the same time. The thermal decomposition and carbonization are preferably effected simultaneously, preferably in the same furnace or reactor.

The carbonization is effected temperatures of preferably above 500 to 1400° C., particularly preferably 700 to 1200° C. and most preferably 900 to 1100° C. Advantageously, carbonization may also be performed at low temperatures. The carbonization temperature can be determined by means of thermogravimetric analysis (TGA). The carbonization temperatures are preferably greater than or equal to the temperatures of the thermal decomposition of polyacrylonitrile.

The heating rate is in the range from preferably 1 to 1000° C. per minute, particularly preferably 1 to 100° C. per minute and most preferably 1 to 10° C. per minute. The heating rate denotes the rise in temperature per unit of time. In an alternative embodiment, the heating rate is in the range from preferably 1 to 20° C. per minute, particularly preferably 1 to 15° C. per minute and most preferably 1 to 10° C. per minute. In a further alternative embodiment, the heating rate is in the range from preferably 10 to 1000° C. per minute, particularly preferably 20 to 500° C. per minute and most preferably 50 to 100° C. per minute.

A stepwise process using different heating rates or intervals without a heating rate is furthermore also possible. For intervals without a heating rate, the reaction mixture is preferably held at a temperature or within a temperature range for a certain amount of time. Intervals without a heating rate advantageously last for example from 30 min to 24 h, preferably 1 to 10 h and particularly preferably 2 to 4 h. Preference is given to intervals without a heating rate at temperatures in the range from 500 to 1200° C., particularly preferably 700 to 1100° C. and most preferably 900 to 1000° C. Below the carbonization temperature, there is preferably no interval without a heating rate.

Cooling can be conducted actively or passively, steadily or in stages.

The duration of the thermal decomposition and/or of the carbonization is guided for example by the temperature selected for this and the desired layer thickness of the carbon coating on the silicon particles. The thermal decomposition and/or the carbonization with preference last from 30 min to 24 h, preferably 1 to 10 h and particularly preferably 2 to 4 h. The process is preferably conducted at a pressure of from 0.5 to 2 bar.

The thermal decomposition and/or the carbonization may be effected in conventional furnaces, such as for example tubular furnaces, calcination furnaces, rotary kilns, belt furnaces, chamber furnaces, retort furnaces or fluidized bed reactors. The heating may be effected by convection or induction, by means of microwaves or plasma. The carbonization is preferably effected in the same apparatus in which the thermal decomposition is also conducted.

The thermal decomposition and/or the carbonization may be conducted with continuous mixing of the reaction mixture or, preferably, statically, i.e. without mixing. The components present in solid form are preferably not fluidized. This reduces the technical complexity.

The preparation of the dry mixture, the thermal decomposition and/or the carbonization may take place under aerobic or, preferably, anaerobic conditions. In particular, the thermal decomposition and/or carbonization preferably take place under anaerobic conditions. Particular preference is given to an inert gas atmosphere, such as a nitrogen or preferably argon atmosphere. The inert gas atmosphere may optionally additionally contain proportions of a reducing gas such as hydrogen. The inert gas atmosphere may be static above the reaction medium or flow over the reaction mixture in the form of a gas flow.

The silicon particles are preferably coated with carbon in just a single coating procedure. Carbon-coated silicon particles are preferably not subjected to a further carbon coating operation.

The carbon-coated silicon particles obtained in accordance with the invention can be sent directly for further use thereof, for example for the production of electrode materials, or alternatively can be freed of oversize or undersize by classifying techniques (sieving, sifting). There are preferably no mechanical aftertreatments or classification, in particular no grinding.

The carbon-coated silicon particles are preferably in the form of isolated particles or loose agglomerates, but not in the form of aggregates of carbon-coated silicon particles. Agglomerates are clusters of multiple carbon-coated silicon particles. Aggregates are assemblies of carbon-coated silicon particles. Agglomerates can be separated into the individual carbon-coated silicon particles, for example using kneading or dispersing methods. Aggregates cannot be separated into the individual particles in this way without destroying carbon-coated silicon particles. However, this does not rule out individual cases in which aggregated carbon-coated silicon particles are formed to a minor extent in the process according to the invention.

The presence of carbon-coated silicon particles in the form of aggregates may for example be visualized using scanning electron microscopy (SEM) or transmission electron microscopy (TEM). A comparison of SEM images and TEM images of the uncoated silicon particles with corresponding images of the carbon-coated silicon particles is particularly suitable for this purpose. Static light scattering methods for determining particle size distributions or particle diameters alone are not suitable for ascertaining the presence of aggregates. However, if the carbon-coated silicon particles have particle diameters that within the scope of measuring accuracy are significantly larger than those of the silicon particles used to produce them, this points towards the presence of aggregated carbon-coated silicon particles. The aforementioned determination methods are particularly preferably used in combination.

The carbon-coated silicon particles exhibit a degree of aggregation of preferably ≤40%, more preferably ≤30%, more preferably still ≤20%, particularly preferably ≤15% and most preferably ≤10%. The degree of aggregation is determined by sieve analysis. The degree of aggregation corresponds the percentage of particles which after dispersion in ethanol with simultaneous treatment with ultrasound do not pass through a sieve with a mesh size of double the d₉₀ value of the volume-weighted particle size distribution of the respective particle composition being analyzed, in particular do not pass through a sieve with a mesh size of 20 μm.

The difference formed from the volume-weighted particle size distributions d₅₀ of the carbon-coated silicon particles and of the silicon particles used as starting material is also an indicator that the carbon-coated silicon particles are not aggregated. The difference formed from the volume-weighted particle size distribution d₅₀ of the carbon-coated silicon particles and the volume-weighted particle size distribution d₅₀ of the silicon particles used as starting material for the production of the carbon-coated silicon particles is preferably ≤5 μm, particularly preferably ≤3 μm and most preferably ≤2 μm.

The carbon-coated silicon particles have volume-weighted particle size distributions with diameter percentiles d₅₀ of preferably ≥2 μm, particularly preferably ≥3 μm and most preferably ≥4 μm. The carbon-coated silicon particles have d₅₀ values of preferably ≤10 μm, particularly preferably ≤8 μm and most preferably ≤6 μm.

The carbon-coated silicon particles have volume-weighted particle size distributions with d₉₀ values of preferably ≤40 μm, particularly preferably d₉₀≤30 μm and very particularly preferably d₉₀≤10 μm.

The carbon-coated silicon particles have volume-weighted particle size distributions with d₁₀ values of preferably ≥0.5 μm, particularly preferably d₁₀≥1 μm and most preferably d₁₀≥1.5 μm.

The particle size distribution of the carbon-coated silicon particles can be bimodal or polymodal and is preferably monomodal, particularly preferably narrow. The volume-weighted particle size distribution of the carbon-coated silicon particles has a width (d₉₀- d₁₀)/d₅₀ of preferably ≥3, more preferably ≥2.5, particularly preferably ≤2 and most preferably ≤1.5.

The volume-weighted particle size distribution of the carbon-coated silicon particles was determined by static laser scattering using the Mie model with a Horiba LA 950 measurement instrument and with ethanol as dispersion medium for the carbon-coated silicon particles.

The carbon coating of the carbon-coated silicon particles has an average layer thickness in the range from preferably 1 to 100 nm, particularly preferably 150 nm (determination method: scanning electron microscopy (SEM) and/or transmission electron microscopy (TEM)).

The carbon-coated silicon particles typically have BET surface areas of preferably 0.1 to 10 m²/g, particularly preferably 0.3 to 8 m²/g and most preferably 0.5 to 5 m²/g (determination in accordance with DIN ISO 9277:2003-05 with nitrogen).

The carbon coating may be porous and is preferably nonporous. The carbon coating has a porosity of preferably ≥2% and particularly preferably ≥1% (determination method for total porosity: 1 minus [quotient of apparent density (determined by means of xylene pycnometry in accordance with DIN 51901) and skeletal density (determined by means of He pycnometry in accordance with DIN 66137-2)]).

The carbon coating of the carbon-coated silicon particles is preferably impermeable to liquid media, such as aqueous or organic solvents or solutions, especially aqueous or organic electrolytes, acids or alkalis.

In general, the silicon particles are not within pores. The carbon coating is generally directly on the surface of the silicon particles.

The carbon coating is generally in the form of a film or is generally not particulate or fibrous. In general, the carbon coating does not contain any particles or any fibers, such as carbon fibers or graphite particles.

In the carbon-coated silicon particles, the silicon particles are partly or preferably fully embedded in carbon. The surface of the carbon-coated silicon particles consists partly or preferably entirely of carbon.

The carbon may be present in the carbon coating in amorphous form or preferably partly or completely in crystalline form.

In general, each carbon-coated silicon particle contains a silicon particle (determination method: scanning electron microscopy (SEM) and/or transmission electron microscopy (TEM)).

The carbon-coated silicon particles may assume any desired shapes and are preferably splintery.

The carbon-coated silicon particles preferably contain 0.1% to 8% by weight, more preferably 0.2% to 5% by weight, more preferably still 0.3% to 3% by weight and particularly preferably 0.5% to 1% by weight of carbon. The carbon-coated silicon particles preferably contain 92% to 99.9% by weight, more preferably 93% to 99% by weight, more preferably still 95% to 99% by weight and particularly preferably 96% to 99% by weight of silicon particles. The above figures in % by weight are based in each case on the total weight of the carbon-coated silicon particles.

The carbon-coated silicon particles have a nitrogen content of preferably 0% to 5% by weight, particularly preferably 0.1% to 3% by weight and most preferably 0.1% to 1% by weight, based on the total weight of the carbon-coated silicon particles (determination method: elemental analysis). Nitrogen is preferably present here chemically bound in the form of heterocycles, for example as pyridine or pyrrole units (N). This is also advantageous for the cycling stability of lithium-ion batteries.

The carbon coating may have oxygen contents, for example, of ≤5% by weight, preferably ≤2% by weight and particularly preferably ≤1% by weight. As well as the main constituents mentioned, it is also possible for further chemical elements to be present, for example in the form of a controlled addition or coincidental impurity: such as Li, Fe, Al, Cu, Ca, K, Na, S, CI, Zr, Ti, Pt, Ni, Cr, Sn, Mg, Ag, Co, Zn, B, P, Sb, Pb, Ge, Bi, rare earths; the contents thereof are preferably ≤1% by weight and particularly preferably ≤100 ppm. The above figures in % by weight are based in each case on the total weight of the carbon coating.

Moreover, the carbon-coated silicon particles may contain one or more conductive additives, for example graphite, conductive carbon black, graphene, graphene oxide, graphene nanoplatelets, carbon nanotubes, carbon fibers or metallic particles such as copper. The carbon-coated silicon particles preferably contain ≤10% by weight and particularly preferably ≤1% by weight of conductive additives, based on the total weight of the carbon-coated silicon particles. Most preferably, no conductive additives are present.

The carbon-coated silicon particles are suitable, for example, as active materials for anode materials of lithium-ion batteries.

The invention further provides processes for producing lithium-ion batteries by using the carbon-coated silicon particles obtained by the process according to the invention as anode active material in the production of anodes for lithium-ion batteries. Lithium-ion batteries generally comprise a cathode, an anode, a separator, and an electrolyte.

Preferably, the cathode, the anode, the separator, the electrolyte and/or another reservoir located in the battery housing contains one or more inorganic salts selected from the group comprising alkali metal, alkaline earth metal and ammonium salts of nitrate (NO₃⁻), nitrite (NO₂⁻), azide (N₃⁻), phosphate (PO₄³⁻), carbonate (CO₃²⁻), borates and fluoride (F⁻). Inorganic salts are particularly preferably present in the electrolyte and/or especially in the anode. Particularly preferred inorganic salts are alkali metal, alkaline earth metal and ammonium salts of nitrate (NO₃⁻), nitrite (NO₂⁻), azide (N₃⁻); lithium nitrate and lithium nitrite are most preferred.

The concentration of the inorganic salts in the electrolyte is preferably 0.01 to 2 molar, particularly preferably 0.01 to 1 molar, more preferably still 0.02 to 0.5 molar and most preferably 0.03 to 0.3 molar. The loading of the inorganic salts in the anode, in the cathode and/or in the separator, in particular in the anode, preferably 0.01 to 5.0 mg/cm², particularly preferably 0.02 to 2.0 mg/cm² and most preferably 0.1 to 1.5 mg/cm², based in each case on the surface area of the anode, of the cathode and/or of the separator.

The anode, the cathode or the separator preferably contains 0.8% to 60% by weight, particularly preferably 1% to 40% by weight and most preferably 4% to 20% by weight of inorganic salts. In the case of the anode, these figures relate to the dry weight of the anode coating, in the case of the cathode they relate to the dry weight of the cathode coating, and in the case of the separator they relate to the dry weight of the separator.

The anode material of the fully charged lithium-ion battery is preferably only partially lithiated. It is thus preferable for the anode material, especially the carbon-coated silicon particles of the invention, to be only partially lithiated in the fully charged lithium-ion battery. “Fully charged” refers to the state of the battery in which the anode material of the battery has its highest loading of lithium. Partial lithiation of the anode material means that the maximum lithium absorption capacity of the silicon particles in the anode material is not exhausted. The maximum lithium absorption capacity of the silicon particles corresponds generally to the formula Li_{4.4}Si and is thus 4.4 lithium atoms per silicon atom. This corresponds to a maximum specific capacity of 4200 mAh per gram of silicon.

The ratio of the lithium atoms to the silicon atoms in the anode of a lithium-ion battery (Li/Si ratio) can be adjusted, for example, via the flow of electric charge. The degree of lithiation of the anode material or of the silicon particles present in the anode material is proportional to the electric charge that has flowed. In this variant, in the course of charging of the lithium-ion battery, the capacity of the anode material for lithium is not fully exhausted. This results in partial lithiation of the anode.

In an alternative, preferred variant, the Li/Si ratio of a lithium-ion battery is adjusted by the cell balancing. In this case, the lithium-ion batteries are designed such that the lithium absorption capacity of the anode is preferably greater than the lithium release capacity of the cathode. The effect of this is that, in the fully charged battery, the lithium absorption capacity of the anode is not fully exhausted, meaning that the anode material is only partly lithiated.

In the case of the partial lithiation of the invention, the Li/Si ratio in the anode material in the fully charged state of the lithium-ion battery is preferably ≤2.2, particularly preferably ≤1.98 and most preferably ≤1.76. The Li/Si ratio in the anode material in the fully charged state of the lithium-ion battery is preferably ≥0.22, particularly preferably ≥0.44 and most preferably ≥0.66.

The capacity of the silicon in the anode material of the lithium-ion battery is preferably utilized to an extent of ≤50%, particularly preferably to an extent of ≤45% and most preferably to an extent of ≤40%, based on a capacity of 4200 mAh per gram of silicon.

The degree of lithiation of silicon or the exploitation of the capacity of silicon for lithium (Si capacity utilization α) can be determined, for example, as described in WO17025346 on page 11, line 4, to page 12, line 25, especially using the formula given therein for the Si capacity utilization α and the supplementary information under the headings “Bestimmung der Delithiierungs-Kapazität β” [Determination of the delithiation capacity β] and “Bestimmung des Si-Gewichtsanteils ω_{Si}” [Determination of the proportion by weight of Si ω_{Si}] (“incorporated by reference”).

The use of the carbon-coated silicon particles produced according to the invention in lithium-ion batteries surprisingly leads to an improvement in the cycle behavior thereof. Such lithium-ion batteries have a small irreversible loss of capacity in the first charging cycle and stable electrochemical behavior with only slight fading in the subsequent cycles. The carbon-coated silicon particles of the invention can thus achieve a small initial loss of capacity and additionally a small continuous loss of capacity of the lithium-ion batteries. Overall, the lithium-ion batteries of the invention have very good stability. This means that, even in the case of a multitude of cycles, barely any fatigue phenomena occur, for example as a result of mechanical destruction of the anode material of the invention or SEI.

These effects can be further increased by adding inorganic salts such as lithium nitrate to the electrolyte.

In the process according to the invention, carbon is advantageously deposited onto silicon particles with a high selectivity. Pure carbon particles or carbon fibers are formed as byproducts to a lesser extent. This increases the yield and also reduces the effort required for separating carbon particles from carbon-coated silicon particles. Preferably, ≥50% by weight, particularly preferably ≥60% by weight and most preferably ≥70% by weight of the carbon is deposited onto the silicon particles, based on the total weight of the gaseous carbon precursors formed from polyacrylonitrile (determination method: elemental analysis). The carbon coating is advantageously attached to the silicon particles here via covalent bonds.

Since the thermal decomposition and/or the carbonization can also be conducted statically, i.e. without fluidization, stirring or other constant mixing of the reaction mixture, the present process can be configured in a technically simple manner. Special equipment can be dispensed with. All this is of great advantage, especially when scaling the process. In addition, compared to conventional CVD processes, the present process is easier to handle since no carbon-containing gases such as ethylene need to be handled, and thus the safety requirements are lower. Overall, the present process can be conducted inexpensively since the production of the dry mixture is also a mere of the starting materials and hence solvents or else customary drying steps, such as spray drying, are therefore unnecessary.

By dispensing with holding stages for the melting of polyacrylonitrile, the amount of time required can be reduced, the space-time yield can be increased and energy can in addition be saved.

Surprisingly, the carbon-coated silicon particles produced according to the invention can be used to obtain lithium-ion batteries which in addition to the aforementioned advantageous cycle behavior also have a high volumetric energy density.

Moreover, the carbon-coated silicon particles produced according to the invention advantageously have a high electrical conductivity and a high resistance to corrosive media, such as for example organic solvents, acids or alkalis. The cell internal resistance of lithium-ion batteries can also be reduced using carbon-coated silicon particles according to the invention.

In addition, the carbon-coated silicon particles produced according to the invention are surprisingly stable in water, especially in aqueous ink formulations for anodes of lithium-ion batteries, meaning that the hydrogen evolution that occurs under such conditions with conventional silicon particles can be reduced. This enables the processing without foaming of the aqueous formulation, the provision of stable electrode slurries and the production of particularly homogeneous and gas bubble-free anodes. In contrast, the silicon particles used as starting material in the process according to the invention release relatively large amounts of hydrogen in water.

With aggregated carbon-coated silicon particles, as are obtained for example when coating silicon particles with carbon using solvents or using drying methods not in accordance with the invention or CVD processes not in accordance with the invention, such advantageous effects cannot be achieved or cannot be achieved to the extent in accordance with the invention.

The examples which follow serve to further illustrate the invention.

Unless stated otherwise, the (comparative) examples below were conducted in air at ambient pressure (1013 mbar) and at room temperature (23° C.). The following methods and materials were used.

Carbonization:

Carbonization was effected with a 1200° C. three-zone tubular furnace (TFZ 12/65/550/E301) from Carbolite GmbH using cascade control including a type N sample thermocouple. The stated temperatures are based on the internal temperature of the tubular furnace at the site of the thermocouple. The starting material to be carbonized in each case was weighed into one or more combustion boats made of quartz glass (QCS GmbH) and introduced into a working tube made of quartz glass. The settings and process parameters used for the carbonizations are reported in the respective examples.

CVD Reactor:

The 1000° C. CVD reactor used (HTR 11/150) from Carbolite GmbH consists of a quartz glass drum that lies within an electrically heated rotary kiln with ceramic lining, in which the temperature is controlled. The heating rate along the reaction zone is between 10 and 20 K/min, the heated drum has a homogeneous temperature distribution in the reaction zone. The temperatures stated are based on the target internal temperature of the drum at the site of the thermocouple.

The glass drum is thermally insulated from the ambient air with the furnace lid closed. During the process, the glass drum is rotated (315°, oscillation frequency 6-8/min) and has bulges in the wall that ensure additional mixing of the powder. The gas conduit is connected to the quartz glass drum. It is possible there, via a bypass, for the bubbler vessel, the temperature of which is controlled by thermostat, to be switched on for the generation of precursor vapor. By-products formed and purge gases are sucked out into the opposite offgas tube. The settings and process parameters used for the chemical gas phase deposition vary according to the precursor used.

Classification/Sieving:

The C-coated Si powders obtained after the carbonization or chemical gas phase deposition were freed of oversize >20 μm by wet sieving with an AS 200 basic sieving machine (Retsch GmbH) with water on stainless steel sieves. The pulverulent product was dispersed (solids content 20%) in ethanol by means of ultrasound (Hielscher UIS250V, amplitude 80%, cycle: 0.75; duration: 30 min) and applied to the sieve tower with a sieve (20 μm). The sieving was conducted with an infinite time preselection and an amplitude of 50-70% with a water stream passing through. The silicon-containing suspension that exited at the bottom was filtered through 200 nm nylon membrane, and the filter residue was dried to constant mass in a vacuum drying cabinet at 100° C. and 50-80 mbar.

The following analytical methods and equipment were used to characterize the C-coated Si particles obtained:

Scanning Electron Microscopy (SEM/EDX):

The microscope analyses were conducted with a Zeiss Ultra 55 scanning electron microscope and an energy-dispersive INCA x-sight x-ray spectrometer. Prior to the analysis, the samples were subjected to vapor deposition of carbon with a Baltec SCD500 sputter/carbon coating unit for prevention of charging phenomena.

Transmission Electron Microscopy (TEM):

The analysis of the layer thickness and of the carbon configuration was conducted on a Zeiss Libra 120 transmission electron microscope. The sample was prepared either by embedding into a resin matrix followed by a microtome section or directly from the powder. This was done by dispersing a spatula-tip of each sample in approx. 2 ml of isopropanol by means of ultrasound and applying it to a copper grid. This was dried on both sides on a hot plate at 100° C. for approx. 1 min.

Inorganic Analysis/Elemental Analysis:

The C contents reported in the examples were ascertained with a Leco CS 230 analyzer; for determination of O and any N contents, a Leco TCH-600 analyzer was used. The qualitative and quantitative determination of other elements in the carbon-coated silicon particles obtained were determined by means of ICP (inductively coupled plasma) emission spectrometry (Optima 7300 DV, from Perkin Elmer). For this purpose, the samples were subjected to acid digestion (HF/HNO₃) in a microwave (Microwave 3000, from Anton Paar). The ICP-OES determination is guided by ISO 11885 “Water quality—Determination of selected elements by inductively coupled plasma optical emission spectrometry (ICP-OES) (ISO 11885:2007); German version EN ISO 11885:2009”, which is used for analysis of acidic aqueous solutions (for example acidified drinking water, wastewater and other water samples, aqua regia extracts of soils and sediments).

Particle Size Determination:

The particle size distribution was determined in accordance with ISO 13320 by means of static laser scattering with a Horiba LA 950. In the preparation of the samples, particular attention must be paid to the dispersing of the particles in the measurement solution in order not to measure the size of agglomerates rather than individual particles. The particles to be analyzed were dispersed in ethanol. For this purpose, the dispersion, prior to the measurement, if required, was treated with 250 W ultrasound in a Hielscher model UIS250v ultrasound laboratory instrument with LS24d₅ sonotrode for 4 min.

Determination of the degree of aggregation of C-coated Si particles:

The determination is effected by means of sieve analysis. The degree of aggregation corresponds the percentage of particles which after dispersion in ethanol with simultaneous treatment with ultrasound do not pass through a sieve with a mesh size of double the d₉₀ value of the volume-weighted particle size distribution of the respective particle composition being analyzed.

BET Surface Area Measurement:

The specific surface area of the materials was measured via gas adsorption with nitrogen using a Sorptomatic 199090 instrument (Porotec) or SA-9603MP instrument (Horiba) by the BET method in accordance with DIN ISO 9277:2003-05.

Si Tightness:

Si Accessibility for Liquid Media:

The determination of the accessibility of silicon in the C-coated Si particles for liquid media was conducted by the following test method on materials having known silicon content (from elemental analysis):

0.5-0.6 g of C-coated silicon was first dispersed by means of ultrasound with 20 ml of a mixture of NaOH (4 M; H₂O) and ethanol (1:1 vol.) and then stirred at 40° C. for 120 min. The particles were filtered through 200 nm nylon membrane, washed to pH neutrality with water and then dried in a drying cabinet at 100° C./50-80 mbar. The silicon content after the NaOH treatment was determined and compared with the Si content prior to the test. The tightness corresponds to the quotient of the Si content of the sample in percent after alkali treatment and the Si content in percent of the untreated C-coated particles.

Determination of Powder Conductivity:

The specific resistance of the C-coated samples was determined in a measurement system from Keithley, 2602 System Source Meter ID 266404, consisting of a pressure chamber (die radius 6 mm) and a hydraulic unit (from Caver, USA, model 38510E-9, S/N: 130306), under controlled pressure (up to 60 MPa).

### EXAMPLE 1 (EX. 1)

Production of Silicon Particles by Means of Grinding:

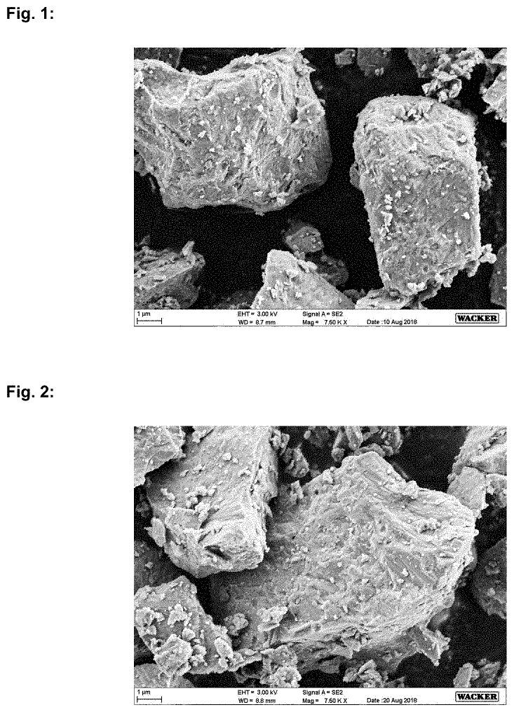

Coarse Si chips from the production of polysilicon were ground using a fluidized bed jet mill (Netzsch-Condux CGS16 with 90 m³/h of nitrogen at 7 bar as grinding gas). The silicon particles thus obtained were in the form of individual, non-aggregated, chip-like particles, as shown in the SEM image (7500× magnification) in FIG. 1. Elemental composition: Si≥98% by weight; C 0.01% by weight; H<0.01% by weight; N<0.01% by weight; O 0.47% by weight.

Particle size distribution: monomodal; D₁₀: 2.19 μm, D₅₀: 4.16 μm, D₉₀: 6.78 μm; (D₉₀−D₁₀)/D₅₀=1.10; (D₉₀−D₁₀)=4.6 μm.

Specific surface area (BET): 2.662 m²/g.

Si tightness: 0%.

Powder conductivity: 2.15 μS/cm.

### EXAMPLE 2 (EX. 2)

C-coating of silicon particles by means of gas phase coating from polyacrylonitrile (PAN):

80.00 g of the silicon particles (Si) from example 1 and 20.00 g of polyacrylonitrile (PAN) were mechanically mixed at 80 rpm for 3 h using a ball mill roller bed (Siemens/Groschopp). 99.00 g of the Si/PAN mixture thus obtained were placed in a quartz glass boat (QCS GmbH) and carbonized, taking the following parameters into account:

nitrogen/H₂ as inert gas, N₂/H₂ flow rate 200 ml/min, and with the following temperature treatment:

heating rate 10° C./min until the temperature reaches 1000° C., holding time 3 h. After cooling, 87.00 g of a black powder were obtained (carbonization yield 88%), which was freed from oversize by means of wet sieving. 79.00 g of C-coated Si particles having a particle size of D₉₉<20 μm were obtained.

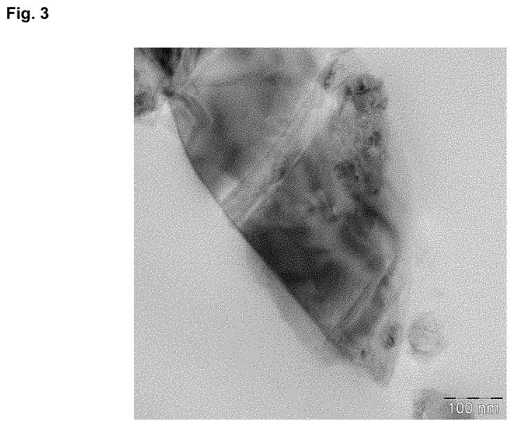

FIG. 2 shows an SEM image (7500× magnification) and FIG. 3 a TEM image (40 000× magnification) of the C-coated Si particles obtained.

Elemental composition: Si≥98% by weight; C 0.7% by weight; H 0.01% by weight; N 0.32% by weight; O 0.7% by weight.

Particle size distribution: monomodal; D₁₀: 2.71 μm, D₅₀: 4.57 μm, D₉₉: 7.30 μm; (D₉₀−D₁₀)/D₅₀=1.00.

Degree of aggregation: 9%.

Specific surface area (BET): 2.51 m²/g.

Si tightness: ˜100% (impermeable).

Powder conductivity: 70820.64 μS/cm.

### COMPARATIVE EXAMPLE 3 (CEX. 3)

C-coating of silicon particles by means of melt coating from polyacrylonitrile (PAN):

As example 2, with the difference that the Si/PAN mixture was subjected to the following temperature treatment in the three-zone tubular furnace:

First: heating rate 10° C./min until a temperature of 300° C. is reached, holding time 90 min, N₂/H₂ flow rate 200 ml/min,

Thereafter: heating rate 10° C./min until a temperature of 1000° C. is reached, holding time 3 h, N₂/H₂ flow rate 200 ml/min.

After cooling, 92.12 g of a black powder were obtained (carbonization yield 94%), which was freed from oversize by means of wet sieving. 87.51 g of C-coated Si particles having a particle size of D₉₉<20 μm were obtained.

Elemental composition: Si≥98% by weight; C 0.5% by weight; H<0.01% by weight; N 0.1% by weight; O 0.61% by weight.

Particle size distribution: monomodal; D₁₀: 2.35 μm, D₅₀: 4.51 μm, D₉₀: 8.01 μm; (D₉₀−D₁₀)/D₅₀=1.26.

Degree of aggregation: 5%.

Specific surface area (BET): 2.46 m²/g.

Si tightness: ˜100% (impermeable).

Powder conductivity: 50678.78 μS/cm.

### COMPARATIVE EXAMPLE 4 (CEX. 4)

C-coating of silicon particles by means of liquid coating from polyacrylonitrile (PAN):

20.00 g of polyacrylonitrile (PAN) were dissolved in 1332 ml of dimethylformamide (DMF) at room temperature. 80.00 g of the silicon powder (Si) from example 1 (D₅₀=4.16 μm) were dispersed in the PAN solution by means of ultrasound (Hielscher UIS250V, amplitude 80%, cycle: 0.9; duration: 30 min). The resulting dispersion was sprayed and dried using a B-290 laboratory spray dryer (BÜCHI GmbH) with B-295 inert loop and B-296 dehumidifier (BÜCHI GmbH) (nozzle tip 0.7 mm; nozzle cap 1.4 mm; nozzle temperature 130° C., N₂ gas flow 30; aspirator 100%; pump 20%). 58.00 g of a brown powder were obtained (58% yield).

57.50 g of the Si/PAN powder thus obtained was placed in a three-zone tubular furnace and subjected to a temperature treatment as described in comparative example 3.

After cooling, 47.15 g of a black powder were obtained (carbonization yield 82%), which was freed from oversize by means of wet sieving. 39.61 g of C-coated Si particles having a particle size of D₉₉<20 μm were obtained.

Elemental composition: Si≥98% by weight; C 0.4% by weight; N 0.17% by weight; O 0.73% by weight.

Particle size distribution: monomodal; D₁₀: 3.69 μm, D₅₀: 6.98 μm, D₉₀: 11.12 μm; (D₉₀−D₁₀)/D₅₀=1.06.

Degree of aggregation: 16%.

Specific surface area (BET): 2.13 m²/g.

Si tightness: ˜100%.

Powder conductivity: 56714.85 μS/cm.

### COMPARATIVE EXAMPLE 5 (CEX. 5)

C-coating of silicon particles by means of gas phase coating from polystyrene (PS):

As example 2, with the difference that polystyrene (PS) was used instead of polyacrylonitrile.

After cooling, 80.00 g of a black powder were obtained (carbonization yield 80%), which was freed from oversize by means of wet sieving. 75.00 g of C-coated Si particles having a particle size of D99<20 μm were obtained.

Elemental composition: Si≥98% by weight; C 0.22% by weight; H<0.01% by weight; N<0.01% by weight; O 0.39% by weight.

Particle size distribution: monomodal; D₁₀: 2.73 μm, D₅₀: 5.02 μm, D₉₀: 8.29 μm; (D₉₀−D₁₀)/D₅₀=1.11.

Degree of aggregation: 6%.

Specific surface area (BET): 1.547 m²/g.

Si tightness: ˜86%.

Powder conductivity: 4084.782 μS/cm.

### COMPARATIVE EXAMPLE 6 (CEX. 6)

C-coating of silicon particles by means of gas phase coating from ethene:

20.00 g of the silicon particles from example 1 (D₅₀=4.16 μm) were transferred at room temperature into the glass tube of the CVD reactor (HTR 11/150) from Carbolite GmbH. The introduction of the sample was followed by a purge procedure with the process gases (10 min argon 3 slm; 3 min ethene and H₂ each 1 slm, 5 min argon 3 slm). With a heating rate of 20 K/min, the reaction zone was heated to 900° C. Even during the purging and heating, the tube was rotated (315° with an oscillation frequency of 8/min) and the powder was mixed. On attainment of the target temperature, there followed a hold time of 10 min. The CVD coating was conducted for a reaction time of 30 min with a total gas flow rate of 3.6 slm with the following gas composition:

2 mol of ethene, 0.3 slm, 8.33% by volume; argon 2.4 slm, 66.67% by volume; H₂ 0.9 slm, 26% by volume.

After cooling, 15.00 g of a black powder were obtained (yield 75%), which was freed from oversize by means of wet sieving. 14.50 g of C-coated Si particles having a particle size of D₉₉<20 μm were obtained.

FIG. 9 shows an SEM image (7500× magnification) and FIG. 10 a TEM image (20 000× magnification) of the C-coated Si particles obtained.

Elemental composition: Si≥94% by weight; C 2.54% by weight; H<0.01% by weight; N<0.01% by weight; O 0.10% by weight.

Particle size distribution: monomodal; D₁₀: 2.79 μm, D₅₀: 5.26 μm, D₉₀: 8.77 μm; (D₉₀−D₁₀)/D₅₀=1.44.

Degree of aggregation: 3%.

Specific surface area (BET): 2.1 m²/g.

Si tightness: ˜100% (impermeable).

Powder conductivity: 818267.37 μS/cm.

### EXAMPLE 7 (EX. 7)

Anode comprising the C-coated silicon particles from example 2 and electrochemical testing in a lithium-ion battery:

29.71 g of polyacrylic acid (dried at 85° C. to constant weight; Sigma-Aldrich, M_{w}˜450 000 g/mol) and 756.60 g of deionized water were agitated by means of a shaker (290 1/min) for 2.5 h until dissolution of the polyacrylic acid was complete. Lithium hydroxide monohydrate (Sigma-Aldrich) was added in portions to the solution until the pH was 7.0 (measured by WTW pH 340i pH meter and SenTix RJD probe). The solution was then mixed by means of a shaker for a further 4 h.

7.00 g of the carbon-coated silicon particles from example 2 were then dispersed in 12.50 g of the neutralized polyacrylic acid solution and 5.10 g of deionized water by means of a dissolver at a circumferential speed of 4.5 m/s for 5 min and of 12 m/s for 30 min while cooling at 20° C. After adding 2.50 g of graphite (Imerys, KS6L C), the mixture was stirred at a circumferential speed of 12 m/s for a further 30 min. After degassing, the dispersion was applied by means of a film applicator with gap height 0.20 mm (Erichsen, model 360) to a copper foil having a thickness of 0.03 mm (Schlenk Metallfolien, SE-Cu58). The anode coating thus produced was then dried at 50° C. and 1 bar air pressure for 60 min.

The average basis weight of the dry anode coating was 3.01 mg/cm² and the coating density 1.0 g/cm³.

The electrochemical studies were conducted on a button cell (CR2032 type, Hohsen Corp.) in a 2-electrode arrangement.

The electrode coating from example 7 was used as counterelectrode or negative electrode (Dm=15 mm); a coating based on lithium-nickel-manganese-cobalt oxide 6:2:2 with a content of 94.0% and average basis weight of 15.9 mg/cm² (sourced from SEI Corp.) was used as working electrode or positive electrode (Dm=15 mm). A glass fiber filter paper (Whatman, GD Type NE) soaked with 60 μl of electrolyte served as separator (Dm=16 mm). The electrolyte used consisted of a 1.0 molar solution of lithium hexafluorophosphate in a 1:4 (v/v) mixture of fluoroethylene carbonate and diethyl carbonate. The cell was constructed in a glovebox (<1 ppm H₂O, O₂); the water content in the dry matter of all components used was below 20 ppm.

The electrochemical testing was conducted at 20° C. The cells were charged by the cc/cv method (constant current/constant voltage) with a constant current of 5 mA/g (corresponding to C/25) in the first cycle and of 60 mA/g (corresponding to C/2) in the subsequent cycles and, on attainment of the voltage limit of 4.2 V, at constant voltage until the current went below 1.2 mA/g (corresponding to C/100) or 15 mA/g (corresponding to C/8). The cell was discharged by the cc method (constant current) with a constant current of 5 mA/g (corresponding to C/25) in the first cycle and of 60 mA/g (corresponding to C/2) in the subsequent cycles until attainment of the voltage limit of 3.0 V. The specific current chosen was based on the weight of the coating of the positive electrode.

On the basis of the formulation, the lithium-ion battery was operated by cell balancing with partial lithiation of the anode.

The results of the electrochemical testing are summarized in table 1.

### EXAMPLE 8 (EX. 8)

Anode comprising the C-coated silicon particles from example 2 with lithium nitrate impregnation of the electrode and electrochemical testing in a lithium-ion battery:

An anode as described in example 7 was produced using the carbon-coated silicon particles from example 2. The anode was additionally modified with LiNO₃ by the following procedure.

The anode from example 7 with a diameter of 15 mm was wetted with 30 μl of an ethanolic LiNO₃ solution (21.7 mg/mlₑₜₕₐₙₒₗ). The impregnated anodes were then dried for 2 h at 80° C. in a drying cabinet and the weight was determined. The amount of LiNO₃ applied to the anode was calculated from the weight difference and given in mg of LiNO₃ per mg of coating weight (mg/mg_{coating}): 0.08 mg/g_{coating} (0.24 mg/cm²_{anode}). The impregnated anode was installed in a lithium-ion battery as described in example 7 and subjected to testing by the same procedure.

The results of the electrochemical testing are summarized in table 1.

### COMPARATIVE EXAMPLE 9 (CEX. 9)

Anode comprising the C-coated silicon particles from comparative example 3 and electrochemical testing in a lithium-ion battery:

A lithium-ion battery was produced and tested, as described above with example 7, with the difference that the carbon-coated silicon particles from comparative example 3 were used.

The results of the electrochemical testing are summarized in table 1.

### COMPARATIVE EXAMPLE 10 (CEX. 10)

Anode comprising the C-coated silicon particles from comparative example 4 and electrochemical testing in a lithium-ion battery:

A lithium-ion battery was produced and tested, as described above with example 7, with the difference that the carbon-coated silicon particles from comparative example 4 were used.

The results of the electrochemical testing are summarized in table 1.

### COMPARATIVE EXAMPLE 11 (CEX. 11)

Anode comprising the C-coated silicon particles from comparative example 5 and electrochemical testing in a lithium-ion battery:

A lithium-ion battery was produced and tested, as described above with example 7, with the difference that the carbon-coated silicon particles from comparative example 5 were used.

The results of the electrochemical testing are summarized in table 1.

### COMPARATIVE EXAMPLE 12 (CEX. 12)

Anode comprising the C-coated silicon particles from comparative example 6 and electrochemical testing in a lithium-ion battery:

A lithium-ion battery was produced and tested, as described above with example 7, with the difference that the carbon-coated silicon particles from comparative example 6 were used.

The results of the electrochemical testing are summarized in table 1.

TABLE 1
Test results of (comparative) examples 7 to 12:

| | | | | | Discharge | |
|---|---|---|---|---|---|---|
| | Si/C | | | | capacity | Number |
| | parti- | | | | after | of cycles |
| | cles | | C | Nitrate | cycle | with ≥80% |
| | from | C pre- | coating | impreg- | 1 [mAh/ | capacity |
| C(Ex.) | (C)Ex. | cursor | process | nation | cm²] | retention |
| 7 | 2 | PAN | CVD | No | 2.10 | 328 |
| 8 | 2 | PAN | CVD | Yes | 2.00 | 492 |
| 9 | 3 | PAN | Melt | No | 2.03 | 290 |
| 10 | 4 | PAN | liquid | No | 1.97 | 271 |
| 11 | 5 | PS | CVD | No | 2.06 | 179 |
| 12 | 6 | Ethene | CVD | No | 1.95 | 167 |

The lithium-ion battery from example 7 according to the invention surprisingly exhibited more stable electrochemical behavior compared to the lithium-ion batteries from comparative examples 9, 10, 11 and 12 with a comparably high discharge capacity after cycle 1.

The lithium-ion battery with added lithium nitrate of example 8 according to the invention surprisingly exhibited even more stable electrochemical behavior.

1-10. (canceled)

11. A process for producing non-aggregated carbon-coated silicon particles, comprising:
providing or producing a dry mixture by mixing silicon particles and polyacrylonitrile present in solid form;
thermally decomposing the polyacrylonitrile present in solid form in the dry mixture to form gaseous carbon precursors; and
forming gaseous carbon precursors that are carbonized in the presence of the silicon particles by CVD processes (chemical vapor deposition, chemical gas phase deposition);
wherein the non-aggregated carbon-coated silicon particles have an average particle diameters d₅₀ of from 1 to 15 μm and containing ≤10% by weight of carbon and ≥90% by weight of silicon, each based on the total weight of the carbon-coated silicon particles.

12. The process of claim 11, wherein the silicon particles and the polyacrylonitrile are present alongside one another as separate particles or granules in the dry mixtures.

13. The process of claim 11, wherein the dry mixture contains 2% to 50% by weight of polyacrylonitrile, based on the total weight of the dry mixture.

14. The process of claim 11, wherein the thermal decomposition of polyacrylonitrile is conducted at temperatures of ≥350° C.

15. The process of claim 11, wherein the proportion of polyacrylonitrile that is melted during the thermal decomposition and carbonization is ≤20% by weight, based on the total weight of the polyacrylonitrile used overall (determination method: thermogravimetric analysis).

16. The process of claim 11, wherein no polyacrylonitrile is melted during the thermal decomposition and carbonization steps.

17. The process of claim 11, wherein the carbon-coated silicon particles exhibit a degree of aggregation of ≤40% (determination by sieve analysis).

18. The process of claim 11, wherein the difference formed from the volume-weighted particle size distribution d₅₀ of the carbon-coated silicon particles and the volume-weighted particle size distribution d₅₀ of the silicon particles used as starting material for the production of the carbon-coated silicon particles is ≤5 μm.

19. The process of claim 11, wherein the thermal decomposition of polyacrylonitrile decomposition products from the group comprising acrylonitrile, acetonitrile, vinylacetonitrile and HCN are formed.

20. The process of claim 11, wherein the dry mixture does not contain any conductive additives selected from the group comprising graphite, conductive carbon black, graphene, graphene oxide, graphene nanoplatelets, carbon nanotubes, carbon fibers and copper.

21. A process for producing lithium-ion batteries, comprising:
providing a lithium-ion battery comprising a cathode, an anode, a separator and/or an electrolyte;
providing or producing a dry mixture by mixing silicon particles and polyacrylonitrile present in solid form;
thermally decomposing the polyacrylonitrile present in solid form in the dry mixture to form gaseous carbon precursors;
forming gaseous carbon precursors that are carbonized in the presence of the silicon particles by CVD processes (chemical vapor deposition, chemical gas phase deposition);
wherein the non-aggregated carbon-coated silicon particles have an average particle diameters d₅₀ of from 1 to 15 μm and containing ≤10% by weight of carbon and ≥90% by weight of silicon, each based on the total weight of the carbon-coated silicon particles; and
wherein the carbon-coated silicon particles obtained are an anode active material for the Lithium-ion battery.

22. The process of claim 21, wherein the cathode, the anode, the separator and/or the electrolyte of the lithium-ion battery and/or another reservoir located in a battery housing contains one or more inorganic salts selected from the group comprising alkali metal, alkaline earth metal and ammonium salts of nitrate, nitrite, azide, phosphate, carbonate, borates and fluoride.
